(19) United States
(12) Patent Application Publication
(10) Pub. No.: US 2024/0241439 A1
(43) Pub. Date: Jul. 18, 2024

(54) PHOTOSENSITIVE RESIN COMPOSITION, CURED FILM AND BLACK MATRIX

(71) Applicant: Advanced Echem Materials Company Limited, Taoyuan (TW)

(72) Inventors: Wei-Cheng Chen, Taoyuan (TW); Jui-Yu Hsu, Taoyuan (TW); Yu-Lun Li, Taoyuan (TW)

(73) Assignee: Advanced Echem Materials Company Limited, Taoyuan (TW)

(21) Appl. No.: 18/398,202

(22) Filed: Dec. 28, 2023

(30) Foreign Application Priority Data
Dec. 30, 2022 (TW) 111150789

(51) Int. Cl. G03F 7/033; G03F 7/00; G03F 7/004; G03F 7/038

(52) U.S. Cl. CPC G03F 7/033; G03F 7/0007; G03F 7/0045; G03F 7/038; G02F 1/133512

(57) ABSTRACT

A photosensitive resin composition, a cured film and a black matrix are provided. The photosensitive resin composition includes an alkali-soluble resin (A), an ethylenically unsaturated monomer (B), a photoinitiator (C), a thermal acid generator (D), a black colorant (E) and a solvent (F). The alkali-soluble resin (A) includes a resin having a fluorene ring and two or more ethylenically polymeric groups (A-1), an epoxy resin (A-2), or a combination thereof. The resin having a fluorene ring and two or more ethylenically polymeric groups (A-1) includes a structural unit represented by Formula (A1) as follows.

In Formula (A1), * represents a bonding position.

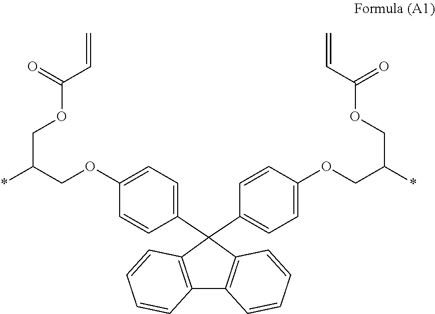 [SMILES: *C(COC(=O)C=C)COc1ccc(C2(c3ccc(OCC(*)COC(=O)C=C)cc3)c3ccccc3-c3ccccc32)cc1]

### CROSS-REFERENCE TO RELATED APPLICATION

This application claims the priority benefit of Taiwan application serial no. 111150789, filed on Dec. 30, 2022. The entirety of the above-mentioned patent application is hereby incorporated by reference herein and made a part of this specification.

### BACKGROUND

### Technical Field

The invention relates to a resin composition, particularly to a photosensitive resin composition, a cured film and a black matrix.

### Description of Related Art

With the vigorous development of liquid crystal display device technologies, in order to improve the contrast and display quality of liquid crystal display devices, black matrixes are usually placed in liquid crystal display devices to prevent phenomena such as decreased contrast and color purity caused by light leakage between pixels, or prevent phenomena such as noise and poor image quality. However, currently used black matrices have phenomena such as insufficient hardness, poor developability, poor patterning, poor light-shielding property, or poor adhesion, which further affect the performance of devices using the black matrix.

### SUMMARY

The invention provides a photosensitive resin composition, a cured film, and a black matrix capable of providing good light-shielding property, resolution, adhesion, hardness and development resistance.

A photosensitive resin composition of the invention includes an alkali-soluble resin (A), an ethylenically unsaturated monomer (B), a photoinitiator (C), a thermal acid generator (D), a black colorant (E) and a solvent (F). The alkali-soluble resin (A) includes a resin having a fluorene ring and two or more ethylenically polymeric groups (A-1), an epoxy resin (A-2), or a combination thereof. The resin having a fluorene ring and two or more ethylenically polymeric groups (A-1) includes a structural unit represented by Formula (A1) as follows:

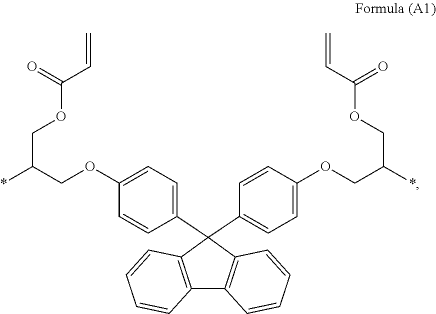

in Formula (A1), * represents a bonding position.

In an embodiment of the invention, a weight average molecular weight of the resin having a fluorene ring and two or more ethylenically polymeric groups (A-1) is 2,000 to 20,000.

In an embodiment of the invention, the epoxy resin (A-2) includes at least one of a structural unit represented by Formula (A2) to Formula (A5) as follows:

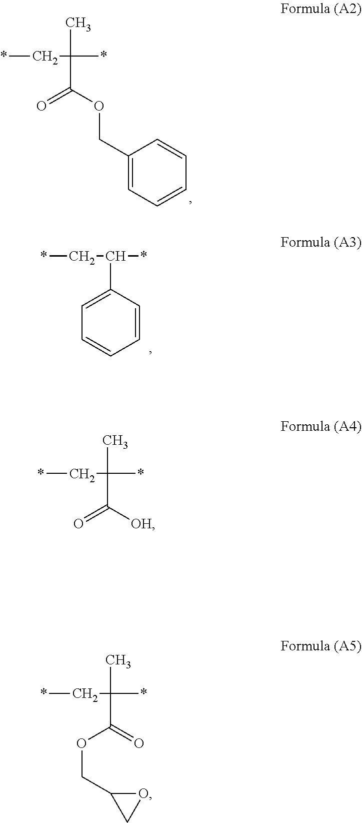

in Formula (A2) to Formula (A5), * represents a bonding position.

In an embodiment of the invention, based on a total mole number of 100 mol % of the structural units in the epoxy resin (A-2), a mole number of the structural unit represented by Formula (A2) is 10 mol % to 40 mol %, a mole number of the structural unit represented by Formula (A3) is 5 mol % to 25 mol %, a mole number of the structural unit represented by Formula (A4) is 5 mol % to 25 mol %, a mole number of the structural unit represented by Formula (A5) is 20 mol % to 45 mol %.

In an embodiment of the invention, a weight average molecular weight of the epoxy resin (A-2) is 11,000 to 18,000.

In an embodiment of the invention, the ethylenically unsaturated monomer (B) includes a bisphenol fluorene-based compound having an epoxy group (B-1), a compound having an ethylenically polymeric group (B-2), a multi-functional compound having an epoxy group (B-3), or a combination thereof.

In an embodiment of the invention, the ethylenically unsaturated monomer (B) includes a bisphenol fluorene-based compound having an epoxy group (B-1). The bisphenol fluorene-based compound having an epoxy group (B-1) includes a compound represented by Formula (B1) as follows:

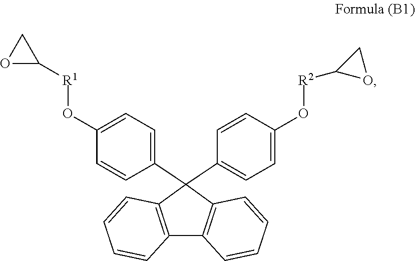

in Formula (B1), R¹ and R² each represent an alkyl group with 1 to 5 carbon atoms, an ether group, a phenyl group, an ester group, or a combination thereof.

In an embodiment of the invention, the ethylenically unsaturated monomer (B) includes a compound having an ethylenically polymeric group (B-2). The compound having an ethylenically polymeric group (B-2) includes a compound represented by Formula (B2) as follows:

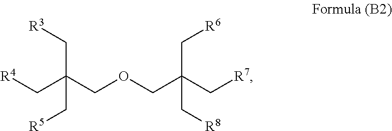

in Formula (B2), R³ to R⁸ each represent hydrogen, an alkyl group, an aryl group, an acrylate group, or a combination thereof.

In an embodiment of the invention, the photoinitiator (C) includes at least one selected from a group consisting of an oxime ester derivative, a halogenated hydrocarbon derivative and an alkyl acetophenone.

In an embodiment of the invention, the thermal acid generator (D) includes a hexafluoroonium salt.

In an embodiment of the invention, based on a usage amount of 100 parts by weight of the alkali-soluble resin (A), a usage amount of the ethylenically unsaturated monomer (B) is 100 parts by weight to 190 parts by weight, a usage amount of the photoinitiator (C) is 10 parts by weight to 50 parts by weight, a usage amount of the thermal acid generator (D) is 60 parts by weight to 96 parts by weight, a usage amount of the black colorant (E) is 200 parts by weight to 250 parts by weight, a usage amount of the solvent (F) is 400 parts by weight to 480 parts by weight.

In an embodiment of the invention, the photosensitive resin composition further includes an additive (G). The additive (G) includes a silane compound having an epoxy group.

In an embodiment of the invention, the photosensitive resin composition further includes a surfactant (H). The surfactant (H) includes a polysiloxane-based surfactant, a cationic-based surfactant, an anionic-based surfactant, a fluorine-based surfactant, or a combination thereof.

A cured film of the invention is formed by the photosensitive resin composition described above.

A black matrix of the invention is the cured film as described above.

Based on the above, the photosensitive resin composition of the invention includes an alkali-soluble resin (A) including a resin including a specific structure having a fluorene ring and two or more ethylenically polymeric groups (A-1), an epoxy resin (A-2), or a combination thereof. Thus, a cured film formed by the photosensitive resin composition may have good light-shielding property, resolution, adhesion, hardness and development resistance, thereby suitable for black matrixes.

To make the features and advantages of the disclosure to be comprehended more easily, embodiments are described in detail as follows.

### DESCRIPTION OF THE EMBODIMENTS

### Photosensitive Resin Composition

The invention provides a photosensitive resin composition including an alkali-soluble resin (A), an ethylenically unsaturated monomer (B), a photoinitiator (C), a thermal acid generator (D), a black colorant (E) and a solvent (F). In addition, the photosensitive resin composition of the invention may further include an additive (G), a surfactant (H) or other suitable additives as needed. The components are described hereinafter in detail.

### Alkali-soluble Resin (A)

The alkali-soluble resin (A) includes a resin having a fluorene ring and two or more ethylenically polymeric groups (A-1), an epoxy resin (A-2), or a combination thereof. The alkali-soluble resin (A) may further include other suitable alkali-soluble resins.

The resin having a fluorene ring and two or more ethylenically polymeric groups (A-1) includes a structural unit represented by Formula (A1) as follows. In this embodiment, a weight average molecular weight of the resin having a fluorene ring and two or more ethylenically polymeric groups (A-1) is 2,000 to 20,000, preferably 3,000 to 10,000.

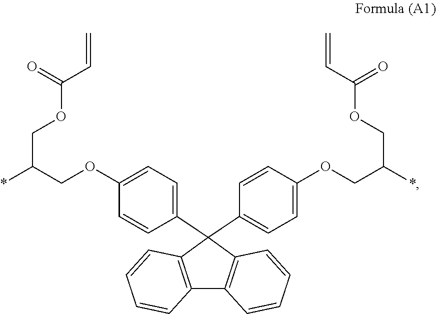

in Formula (A1), * represents a bonding position.

In addition, the structural unit represented by Formula (A1) is derived from a monomer represented by Formula (A1-1) as follows.

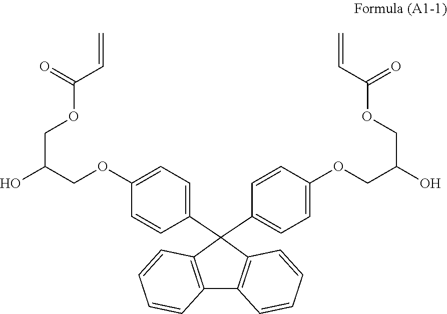

The resin having a fluorene ring and two or more ethylenically polymeric groups (A-1) may be a cardo resin formed by polymerizing a monomer having a fluorene ring and two or more ethylenically-polymerizable groups, tetracarboxylic dianhydride, and dicarboxylic acid, wherein the monomer having a fluorene ring and two or more ethylenically-polymerizable groups is preferable the monomer represented by Formula (A1-1) above. Tetracarboxylic dianhydride and dicarboxylic acid are not particularly limited, and suitable tetracarboxylic dianhydride and dicarboxylic acid may be selected as needed. For example, the compound forming a structural unit having a fluorene ring and two or more ethylenically-polymerizable groups may include a bisphenol fluorene-based compound having two or more ethylenically-polymerizable groups obtained by reacting a bisphenol fluorene-based compound with an ethylenically unsaturated group compound. The bisphenol fluorene-based compound may include 9,9-bis(4-hydroxyphenyl) fluorene, 9,9-bis(4-hydroxy-3-methylphenyl) fluorene, 9,9-bis(4-amino-3-chlorophenyl) fluorene, 9,9-bis(4-bromophenyl)-9H-fluorene, 9,9-bis(4-amino-3-fluorophenyl) fluorene or other suitable bisphenol fluorene-based compounds. The method of synthesizing the resin having a fluorene ring and two or more ethylenically polymeric groups (A-1) is not particularly limited, and a monomer having a fluorene ring and two or more ethylenically-polymerizable groups, tetracarboxylic dianhydride, and dicarboxylic acid may be polymerized into a structural unit having a fluorene ring and two or more ethylenically-polymerizable groups using a conventional organic synthesis method.

Specific examples of the resin having a fluorene ring and two or more ethylenically polymeric groups (A-1) include a cardo resin (trade name: KBR series, manufactured by KISCO Ltd.).

Based on a usage amount of 100 parts by weight of the alkali-soluble resin (A), a usage amount of the resin having a fluorene ring and two or more ethylenically polymeric groups (A-1) is 10 parts by weight to 90 parts by weight, preferably 11.11 parts by weight to 77.78 parts by weight.

When the alkali-soluble resin (A) in the photosensitive resin composition includes the resin having a fluorene ring and two or more ethylenically polymeric groups (A-1), the resin having a fluorene ring and two or more ethylenically polymeric groups (A-1) contributes to improve the dispersibility in the photosensitive resin composition, so that a cured film formed by the photosensitive resin composition may have better resolution and development resistance.

The epoxy resin (A-2) is not particularly limited, and any suitable epoxy resin may be selected according to needs. In this embodiment, a weight average molecular weight of the epoxy resin (A-2) is 11,000 to 18,000, preferably 14,000 to 17,000. The epoxy resin (A-2) may be used alone or in combination. In this embodiment, the epoxy resin (A-2) may include at least one of structural units represented by Formula (A2) to Formula (A5) as follows.

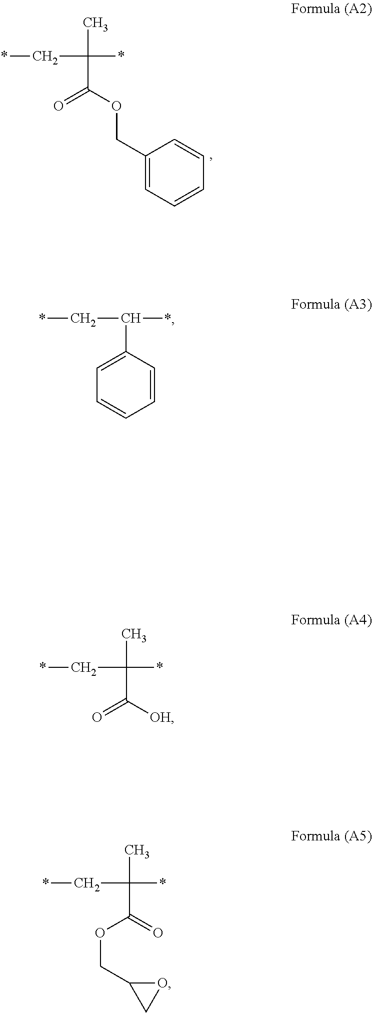

in Formula (A2) to Formula (A5), * represents a bonding position.

Based on a sum of 100 mol % of the structural unit in the epoxy resin (A-2), the structural unit represented by Formula (A2) is 10 mol % to 40 mol %, preferably 20 mol % to 40 mol %; the structural unit represented by Formula (A3) is 5 mol % to 25 mol %, preferably 10 mol % to 20 mol %; the structural unit represented by Formula (A4) is 5 mol % to 25 mol %, preferably 10 mol % to 20 mol %; the structural unit represented by Formula (A5) is 20 mol % to 45 mol %, preferably 20 mol % to 35 mol %.

Based on a usage amount of 100 parts by weight of the alkali-soluble resin (A), a usage amount of the epoxy resin (A-2) is 10 parts by weight to 95 parts by weight, preferably 22.22 parts by weight to 88.89 parts by weight.

When the alkali-soluble resin (A) in the photosensitive resin composition includes the epoxy resin (A-2), the epoxy resin (A-2) contributes to improve the crosslinking ability of the secondary curing, so that a cured film formed by the photosensitive resin composition may have better resolution, adhesion and hardness.

### Ethylenically Unsaturated Monomer (B)

The ethylenically unsaturated monomer (B) is not particularly limited, and any suitable ethylenically unsaturated monomer may be selected according to needs. In this embodiment, the ethylenically unsaturated monomer (B) may include a bisphenol fluorene-based compound having an epoxy group (B-1), a compound having an ethylenically polymeric group (B-2), a multi-functional compound having an epoxy group (B-3), or a combination thereof.

In this embodiment, the bisphenol fluorene-based compound having an epoxy group (B-1) may include a compound represented by Formula (B1) as follows or other suitable bisphenol fluorene-based compounds having an epoxy group.

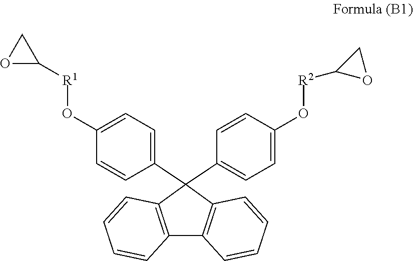

In Formula (B1), R¹ and R² each represent an alkyl group with 1 to 5 carbon atoms, an ether group, a phenyl group, an ester group, or a combination thereof; preferably an alkyl group with 1 to 5 carbon atoms, an ether group, or a combination thereof.

Based on a usage amount of 100 parts by weight of the alkali-soluble resin (A), a usage amount of the bisphenol fluorene-based compound having an epoxy group (B-1) is 10 parts by weight to 30 parts by weight, preferably 10 parts by weight to 20 parts by weight.

When the ethylenically unsaturated monomer (B) in the photosensitive resin composition includes the bisphenol fluorene-based compound having an epoxy group (B-1), the bisphenol fluorene-based compound having an epoxy group (B-1) contributes to improve the crosslinking ability of the secondary curing, so that a cured film formed by the photosensitive resin composition may have better hardness.

In this embodiment, the compound having an ethylenically polymeric group (B-2) may include a compound represented by Formula (B2) as follows or other suitable compounds having an ethylenically polymeric group.

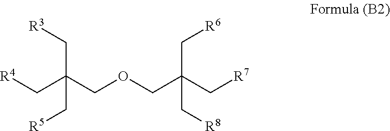

In Formula (B2), R³ to R⁸ each represent hydrogen, an alkyl group, an aryl group, an acrylate group, or a combination thereof, preferably at least one of R³ to R⁸ includes an acrylate group, more preferably at least four of R³ to R⁸ include an acrylate group, much more preferably all of R³ to R⁸ include an acrylate group.

Based on a usage amount of 100 parts by weight of the alkali-soluble resin (A), a usage amount of the compound having an ethylenically polymeric group (B-2) is 50 parts by weight to 80 parts by weight, preferably 65 parts by weight to 80 parts by weight.

The multi-functional compound having an epoxy group (B-3) is not particularly limited, and any suitable multi-functional compound having an epoxy group may be selected according to needs. In this embodiment, the multi-functional compound having an epoxy group (B-3) does not include a compound having a fluorene group. For example, the multi-functional compound having an epoxy group (B-3) may include (chloromethyl)oxirane, (bisphenol A-epichlorohydrin) glycidyl end-capped, 4,4′-(propane-2,2-diyl)bis(cyclohexan-1-ol) compound with 2-(chloromethyl)oxirane, 1,1-bis(2,3-epoxypropoxy)phenylethane, 4,6-bis(1-adamantyl)-1,3-digylcidyloxybenzene, 4-glycidyloxycarbazole, N-(4-(oxiranylmethoxy)-1,2-epoxypropane, bisphenol A diglycidyl ether and its derivatives, 1-(4-benzyloxyphenoxy)-2,3-epoxypropane or other multi-functional compounds having an epoxy group, preferably bisphenol A diglycidyl ether and its derivatives. The multi-functional compound having an epoxy group (B-3) may be used alone or in combination.

Based on a usage amount of 100 parts by weight of the alkali-soluble resin (A), a usage amount of the multi-functional compound having an epoxy group (B-3) is 30 parts by weight to 90 parts by weight, preferably 50 parts by weight to 85 parts by weight.

Based on a usage amount of 100 parts by weight of the alkali-soluble resin (A), a usage amount of the ethylenically unsaturated monomer (B) is 100 parts by weight to 190 parts by weight, preferably 140 parts by weight to 180 parts by weight.

### Photoinitiator (C)

The photoinitiator (C) is not particularly limited, and any suitable photoinitiator may be selected according to needs. In this embodiment, the photoinitiator (C) may include at least one selected from a group consisting of an oxime ester derivative, a halogenated hydrocarbon derivative and an alkyl acetophenone, preferably an oxime ester derivative.

The oxime ester derivative may include a compound represented by Formula (C1) as follows, a compound represented by Formula (C2) as follows, a compound represented by Formula (C3) as follows, 1-[4-(phenylthio)phenyl]-1,2-octanedione 2-(O-benzoyloxime), 1-(6-o-methylbenzoyl-9-ethylcarbazol-3-yl)-(3-ethanone)-1-oxime-acetate, OXE04 (trade name; manufactured by BASF), 1-[9-ethyl-6-[2-methyl-4-[(tetrahydro-2-furyl)methoxy]benzoyl]-9H-carbazol-3-yl]-1-(O-acetyloxime)ethenone or other suitable oxime ester derivatives, preferably the compound represented by Formula (C1) or the compound represented by Formula (C2). The oxime ester derivative may be used alone or in combination.

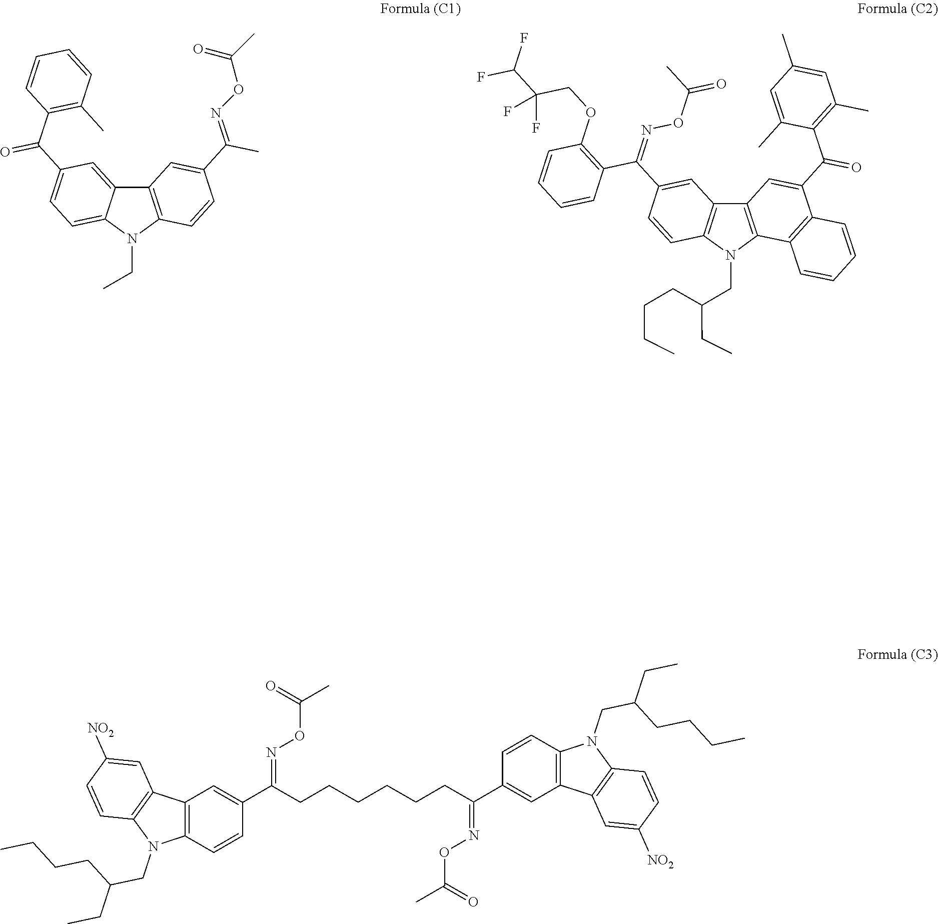 [SMILES: CCn1c2ccc(C(=O)c3ccccc3C)cc2c2cc(/C(C)=N/OC(C)=O)ccc21 ; CCCCC(CC)Cn1c2ccc(/C(=N\OC(C)=O)c3ccccc3OCC(F)(F)C(F)F)cc2c2cc(C(=O)c3c(C)cc(C)cc3C)c3ccccc3c21 ; CCCCC(CC)Cn1c2ccc(/C(CCCCCC/C(=N\OC(C)=O)c3ccc4c(c3)c3cc([N+](=O)[O-])ccc3n4CC(CC)CCCC)=N/OC(C)=O)cc2c2cc([N+](=O)[O-])ccc21]

The halogenated hydrocarbon derivative may include chloromethane, vinyl chloride, chlorobenzene or other suitable halogenated hydrocarbon derivatives. The halogenated hydrocarbon derivative may be used alone or in combination.

The alkyl acetophenone may include p-alkyl acetophenone, m-alkyl acetophenone or other suitable alkyl acetophenones. The alkyl acetophenone may be used alone or in combination.

Based on a usage amount of 100 parts by weight of the alkali-soluble resin (A), a usage amount of the photoinitiator (C) is 10 parts by weight to 50 parts by weight, preferably 20 parts by weight to 40 parts by weight.

### Thermal Acid Generator (D)

The thermal acid generator (D) is not particularly limited, and any suitable thermal acid generator may be selected according to needs. In this embodiment, the thermal acid generator (D) may include a hexafluoroonium salt or other suitable thermal acid generator, preferably a hexafluoroonium salt.

The hexafluoroonium salt may include a compound represented by Formula (D1) as follows, triarylsulfonium hexafluoroantimonate salt, bis(4-methylphenyl)iodonium hexafluorophosphate, (4-methylphenyl) [4-(2-methylpropyl)phenyl] iodonium hexafluorophosphate, 4-isopropyl-4′-methyldiphenyliodonium tetrakis(pentafluorophenyl)borate, diaryliodonium hexafluorophosphate (e.g. xylyliodonium hexafluorophosphate) or other suitable hexafluoroonium salts. The hexafluoroonium salt preferably includes the compound represented by Formula (D1). The hexafluoroonium salt may be used alone or in combination.

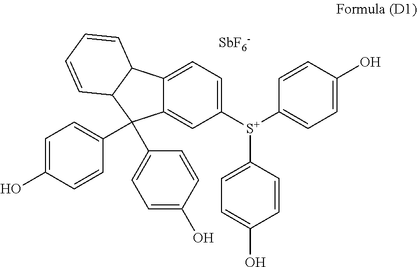 [SMILES: Oc1ccc([S+](c2ccc(O)cc2)c2ccc3c(c2)C(c2ccc(O)cc2)(c2ccc(O)cc2)C2C=CC=CC32)cc1 ; "SbF6-"]

When the photosensitive resin composition includes the thermal acid generator (D), the thermal acid generator (D) may be used as, for example, a crosslinking accelerator, to obtain a photosensitive resin composition with good hardness and a cured film formed therefrom with good hardness, resolution, adhesion and development resistance.

Based on a usage amount of 100 parts by weight of the alkali-soluble resin (A), a usage amount of the thermal acid generator (D) is 60 parts by weight to 96 parts by weight, preferably 70 parts by weight to 90 parts by weight.

### Black Colorant (E)

The black colorant (E) is not particularly limited, and any suitable black colorant may be selected according to needs. For example, the black colorant (E) may be composed of one or more organic black pigments, inorganic black pigments or a combination thereof through grinding and dispersion. The organic black pigment may include lactam-based organic black, RGB black, RVB black, and the like. The inorganic black pigment may include nigrosine, perylene black, titanium black, cyanine black, lignin black, carbon black, or a combination thereof. RGB black, RVB black, and the like represent pigments showing black color by mixing at least two kinds of color pigments among red pigments, green pigments, blue pigments, violet pigments, yellow pigments, purple pigments, and the like. The black colorant (E) preferably includes carbon black.

Based on a usage amount of 100 parts by weight of the alkali-soluble resin (A), a usage amount of the black colorant (E) is 200 parts by weight to 250 parts by weight, preferably 210 parts by weight to 240 parts by weight.

When the photosensitive resin composition includes the black colorant (E), a cured film formed by the photosensitive resin composition may have light-shielding property, thereby suitable for black matrixes. At the same time, when the usage amount of the black colorant (E) falls into the above range, a cured film formed by the photosensitive resin composition may have good light-shielding property (for example, transmittance less than or equal to 1.5%).

### Solvent (F)

The solvent (F) is not particularly limited, and any suitable solvent may be selected according to needs. The solvent (F) is preferably a solvent having a boiling point of 100° C. to 250° C. under normal pressure. The solvent (F) may include an ester-based organic solvent, an ether-based organic solvent, an ether ester-based organic solvent, a ketone-based organic solvent, an aromatic hydrocarbon organic solvent, a nitrogen-containing organic solvent or other suitable solvents. The ester-based organic solvent may include methyl 2-hydroxypropionate, ethyl 2-hydroxypropionate, ethyl 2-hydroxy-2-methylpropionate, 3-methyl-3-methoxybutyl propionate, methyl 3-methoxypropionate, ethyl 3-methoxypropionate, methyl 3-ethoxypropionate, ethyl 3-ethoxypropionate, ethyl ethoxyacetate, n-pentyl formate or other suitable ester-based organic solvents. The ether-based organic solvent may include ethylene glycol monomethyl ether, ethylene glycol monoethyl ether, ethylene glycol monoisopropyl ether, ethylene glycol monobutyl ether, diethylene glycol monomethyl ether, diethylene glycol monoethyl ether, propylene glycol monomethyl ether, propylene glycol monobutyl ether, diethylene glycol diethyl ether, diethylene glycol dimethyl ether, diethylene glycol methyl ethyl ether or other suitable ether-based organic solvents. The ether ester-based organic solvent may include ethylene glycol monomethyl ether acetate, ethylene glycol monoethyl ether acetate, ethylene glycol monobutyl ether acetate, propylene glycol monomethyl ether acetate (PGMEA), propylene glycol monoethyl ether acetate or other suitable ether ester-based organic solvents. The ketone-based organic solvent may include methyl isobutyl ketone or other suitable ketone-based organic solvents. The nitrogen-containing organic solvent may include N-methylpyrrolidone, N,N-dimethylformamide or N,N-dimethylacetamide or other suitable nitrogen-containing organic solvents. In this embodiment, the solvent (F) is preferable an ether ester-based organic solvent, more preferable propylene glycol monomethyl ether acetate. The solvent (F) may be used alone or in combination.

Based on a usage amount of 100 parts by weight of the alkali-soluble resin (A), a usage amount of the solvent (F) may be 400 parts by weight to 480 parts by weight, preferably 410 parts by weight to 470 parts by weight.

When the photosensitive resin composition includes the solvent (F), the photosensitive resin composition may have proper viscosity, thereby having good coating uniformity, so that a cured film with good surface flatness is formed.

### Additive (G)

In this embodiment, the additive (G) may include a silane compound having an epoxy group. The silane compound having an epoxy group may include glycidyl trimethoxysilane, 3-glycidyl ether oxypropyl trimethoxysilane, 3-glycidyl ether oxypropyl triethoxysilane, 3-glycidyl ether oxypropyl dimethylmethoxysilane, 1-(3-glycidyl ether propyl)-1,1,3,3,3-pentaethoxy-1,3-disilane, 3-glycidyl ether propyl heptamethyl cyclotetrasiloxane, (3-glycidyl ether oxypropyl) methyl-dimethyl copolysiloxane, monoglycidyl ether propyl end-capped polydimethylsiloxane, tert-butyldimethylsilyl glycidyl ether, mono(2,3-epoxy)propyl ether end-capped polydimethylsiloxane, or other suitable monomers, preferably glycidyl trimethoxysilane. The additive (G) may be used alone or in combination.

Based on a usage amount of 100 parts by weight of the alkali-soluble resin (A), a usage amount of the additive (G) may be 20 parts by weight to 70 parts by weight, preferably 30 parts by weight to 60 parts by weight.

When the photosensitive resin composition includes an additive (G), and the additive (G) includes a silane compound having an epoxy group, the silane compound having an epoxy group contributes to improve the adhesion between the photosensitive resin composition and the substrate, so that a cured film formed by the photosensitive resin composition may have better resolution and adhesion.

### Surfactant (H)

The surfactant (H) is not particularly limited, and any suitable surfactant may be selected according to needs. In this embodiment, the surfactant (H) may include a polysiloxane-based surfactant, a cationic-based surfactant, an anionic-based surfactant, a fluorine-based surfactant, or a combination thereof, preferably a polysiloxane-based surfactant, more preferably polyester modified polydimethylsiloxane. The surfactant (G) may be used alone or in combination.

Based on a usage amount of 100 parts by weight of the alkali-soluble resin (A), a usage amount of the surfactant (H) is 5 parts by weight to 40 parts by weight, preferably 10 parts by weight to 30 parts by weight.

### Preparation of Photosensitive Resin Composition

The preparation of the photosensitive resin composition is not particularly limited. For example, the alkali-soluble resin (A), the ethylenically unsaturated monomer (B), the photoinitiator (C), the thermal acid generator (D), the black colorant (E) and the solvent (F) are stirred in a mixer to be mixed uniformly into a solution state, and an additive (G), a surfactant (H) or other suitable additives may also be added if necessary. After mixing them uniformly, a liquid photosensitive resin composition is obtained.

### Manufacturing Process of Cured Film

An exemplary embodiment of the invention provides a cured film formed by the photosensitive resin composition above.

The cured film may be formed by coating the photosensitive resin composition above on a substrate to form a coating film and performing pre-bake, exposure, development, and post-bake on the coating film. For example, after the photosensitive resin composition is coated on the substrate to form a coating film, pre-bake is performed at a temperature of 80 to 120° C. for 2 to 3 minutes. Next, the pre-baked coating film is exposed with a light at 200 to 1000 mJ/cm². Then, the exposed coating film is developed for 100 to 130 seconds. Next, post-bake is performed at 220° C. for 5 minutes to form a cured film on the substrate.

The substrate may be a glass substrate, a wafer substrate or a plastic base material (for example, a polyethersulfone (PES) board or a polycarbonate (PC) board), and the type thereof is not particularly limited.

The coating method is not particularly limited, but a spray coating method, a roll coating method, a spin coating method, or the like may be used, and in general, a spin coating method is widely used. In addition, a coating film is formed, and then, in some cases, residual solvent may be partially removed under reduced pressure.

The developing solution is not particularly limited, and a suitable developing solution may be selected as needed. For example, the developing solution may be tetramethyl ammonium hydroxide (TMAH), and the concentration thereof may be 0.28 wt %.

### Manufacturing Process of Black Matrix

An exemplary embodiment of the invention provides a black matrix, which is the cured film above.

The manufacturing process of the black matrix may be the same as the above manufacturing process of cured film, and is not repeated herein.

The invention is described hereinafter in detail with reference to some examples. The following examples are provided to describe the invention, and the scope of the invention includes the categories described in the following claims, their equivalents, and their modifications. The invention is not limited to the scope of those examples.

### Examples of Photosensitive Resin Composition and Cured Film

Example 1 to Example 3 and Comparative example 1 to Comparative example 4 of the photosensitive resin composition and the cured film are described below:

### EXAMPLE 1

### a. Photosensitive Resin Composition

77.78 parts by weight of the cardo resin (trade name: KBR series, manufactured by KISCO Ltd.), 22.22 parts by weight of the epoxy resin including the structural units represented by Formula (A2) to Formula (A5), 11.11 parts by weight of the compound represented by Formula (B1-1), 77.78 parts by weight of dipentaerythritol hexaacrylate, 77.78 parts by weight of the compound represented by Formula (B3-1), 33.33 parts by weight of the compound represented by Formula (C2), 88.89 parts by weight of the hexafluoroonium salt represented by Formula (D1), 222.22 parts by weight of carbon black and 44.44 parts by weight of glycidyl trimethoxysilane were added in 455.56 parts by weight of propylene glycol monomethyl ether acetate. After stirring uniformly with a stirrer, the photosensitive resin composition of Example 1 was obtained.

### b. Cured Film

Each photosensitive resin composition prepared in the examples was coated on a substrate by a spin coating method (spin coater model: MK-8, manufactured by Tokyo Electron Limited, rotation speed: 580 rpm). Next, pre-bake was performed at a temperature of 95° C. for 3 minutes to form a film. Then, the pre-baked coating film is exposed at 800 mJ/cm² using a I line stepper (model: FPA 5500 iZa, manufactured by Canon Inc.) to form a semi-finished product. Next, development was performed using tetramethyl ammonium hydroxide having a concentration of 0.28 wt % as a developing solution for 60 to 300 seconds. Then, post-bake was performed at 220° C. for 20 minutes to obtain the cured film. The resolution, adhesion and development resistance of the obtained cured films were evaluated by each of the following evaluation methods, and the results thereof are as shown in Table 2.

### EXAMPLE 2 TO EXAMPLE 3 AND COMPARATIVE EXAMPLE 1 TO COMPARATIVE EXAMPLE 4

The photosensitive resin compositions of Example 2 to Example 3 and Comparative example 1 to Comparative example 4 were prepared using the same steps as Example 1, and the difference thereof is: the type and the usage amount of the components of the photosensitive resin compositions were changed (as shown in Table 1). The obtained photosensitive resin compositions were made into cured films and evaluated by each of the following evaluation methods, and the results thereof are as shown in Table 2.

TABLE 1

| | Symbol | Components/compounds |
|---|---|---|
| Alkali-soluble resin | A-1 | Cardo resin, for which a weight average molecular weight |
| (A) | | thereof is 5,150 (trade name: KBR series, manufactured by |
| | | KISCO Ltd.). |
| | A-2 | Epoxy resin including a structural unit represented by |
| | | Formula (A2) to Formula (A5), for which a weight average |
| | | molecular weight thereof is 15,000, |
| | | wherein based on a total mole number of 100 mol% of the |
| | | structural units in the epoxy resin, a mole number of the |
| | | structural unit represented by Formula (A2) is 35 mol%, a |
| | | mole number of the structural unit represented by Formula |
| | | (A3) is 20 mol%, a mole number of the structural unit |
| | | represented by Formula (A4) is 20 mol%, a mole number of |
| | | the structural unit represented by Formula (A5) is 25 mol%. |
| Ethylenically | B-1 | Compound represented by Formula (B1-1). |
| unsaturated monomer (B) | | 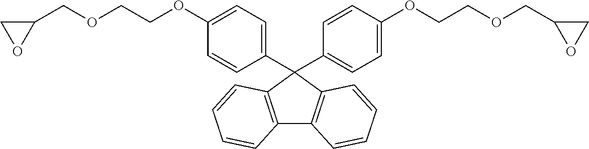 [SMILES: c1ccc2c(c1)-c1ccccc1C2(c1ccc(OCCOCC2CO2)cc1)c1ccc(OCCOCC2CO2)cc1] |
| | | Formula (B1-1) |
| | B-2 | Dipentaerythritol hexaacrylate (DPHA). |
| | B-3 | Compound represented by Formula (B3-1). |
| | | 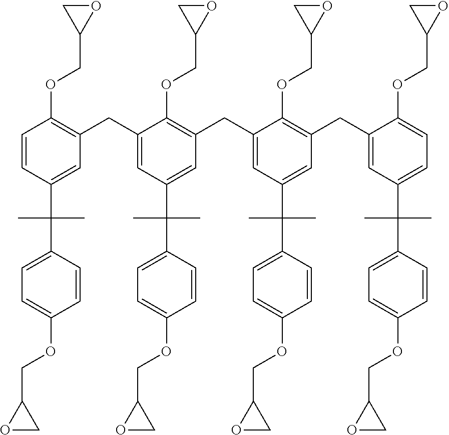 [SMILES: CC(C)(c1ccc(OCC2CO2)cc1)c1ccc(OCC2CO2)c(Cc2cc(C(C)(C)c3ccc(OCC4CO4)cc3)cc(Cc3cc(C(C)(C)c4ccc(OCC5CO5)cc4)cc(Cc4cc(C(C)(C)c5ccc(OCC6CO6)cc5)ccc4OCC4CO4)c3OCC3CO3)c2OCC2CO2)c1] |
| | | Formula (B3-1) |
| Photoinitiator (C) | C-1 | Compound represented by Formula (C2). |
| | | 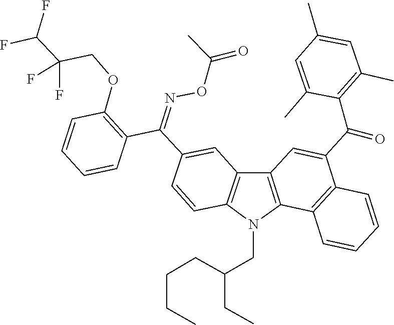 [SMILES: CCCCC(CC)Cn1c2ccc(/C(=N\OC(C)=O)c3ccccc3OCC(F)(F)C(F)F)cc2c2cc(C(=O)c3c(C)cc(C)cc3C)c3ccccc3c21] |
| | | Formula (C2) |
| Thermal acid | D-1 | Hexafluoroonium salt represented by Formula (D1). |
| generator (D) | | 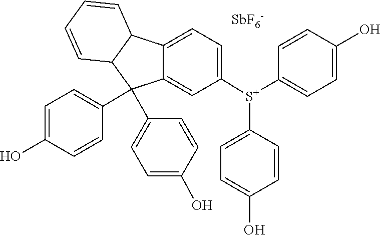 [SMILES: Oc1ccc([S+](c2ccc(O)cc2)c2ccc3c(c2)C(c2ccc(O)cc2)(c2ccc(O)cc2)C2C=CC=CC32)cc1 ; "SbF6-"] |
| | | Formula (D1) |
| Black colorant (E) | E-1 | Carbon black. |
| Solvent (F) | F-1 | Propylene glycol monomethyl ether acetate (PGMEA). |
| Additive (G) | G-1 | Glycidyl trimethoxysilane. |

TABLE 2

| Component | | Examples | | | Comparative examples | | | |
|---|---|---|---|---|---|---|---|---|
| (unit: parts by weight) | | 1 | 2 | 3 | 1 | 2 | 3 | 4 |
| Alkali-soluble | A-1 | 77.78 | 50.00 | 11.11 | — | 100.00 | 50.00 | 50.00 |
| resin (A) | A-2 | 22.22 | 50.00 | 88.89 | 100.00 | — | 50.00 | 50.00 |
| Ethylenically | B-1 | 11.11 | 11.11 | 11.11 | 11.11 | 11.11 | — | 11.11 |
| unsaturated | B-2 | 77.78 | 77.78 | 77.78 | 77.78 | 77.78 | 77.78 | 77.78 |
| monomer (B) | B-3 | 77.78 | 77.78 | 77.78 | 77.78 | 77.78 | 77.78 | 77.78 |
| Photoinitiator | C-1 | 33.33 | 33.33 | 33.33 | 33.33 | 33.33 | 33.33 | 33.33 |
| (C) | | | | | | | | |
| Thermal acid | D-1 | 88.89 | 88.89 | 88.89 | 88.89 | 88.89 | 88.89 | 88.89 |
| generator (D) | | | | | | | | |
| Black colorant | E-1 | 222.22 | 222.22 | 222.22 | 222.22 | 222.22 | 222.22 | 222.22 |
| (E) | | | | | | | | |
| Solvent (F) | F-1 | 455.56 | 455.56 | 455.56 | 455.56 | 455.56 | 466.67 | 500.00 |
| Additive (G) | G-1 | 44.44 | 44.44 | 44.44 | 44.44 | 44.44 | 44.44 | — |
| Evaluation | Light-shielding | ◯ | ◯ | ◯ | ◯ | ◯ | ◯ | ◯ |
| results | property | | | | | | | |
| | Resolution | ◯ | ◯ | ◯ | X | X | ◯ | X |
| | Adhesion | ◯ | ◯ | ◯ | ◯ | Δ | ◯ | X |
| | Hardness | ◯ | ◯ | ◯ | ◯ | Δ | Δ | ◯ |
| | Development resistance | ◯ | ◯ | ◯ | X | ◯ | ◯ | ◯ |

### Evaluation Methods

### a. Light-shielding Property

Each photosensitive resin composition prepared in the examples was coated on a substrate by a spin coating method (spin coater model: MS-A150, manufactured by MIKASA Corporation, rotation speed: 580 rpm). Next, pre-bake was performed at a temperature of 90° C. for 2 minutes. Then, the exposure was performed at 250 mJ/cm² light using an I-line stepper (model: UX-1000SM, manufactured by USHIO TAIWAN, INC.) to form a semi-finished product. Next, post-bake was performed at 220° C. for 20 minutes to obtain the cured films.

The prepared cured film (thickness: 1.5 μm) was measured for a transmittance on the film at wavelength of 700 nm via a colorimeter (Model: MCPD-3000, manufactured by OTSUKA TECH ELECTRONICS CO., LTD.) to evaluate the light-shielding property. When the transmittance is lower, the cured film has good light-shielding property.

The evaluation criteria of light-shielding property are as follows:
◯: transmittance≤1.5%;
Δ: 1.5%<transmittance≤2.5%;
X: 2.5%<transmittance.

### b. Resolution

The prepared cured film (thickness: 1.5 μm) was observed via an electron microscope (Model: MX-50, manufactured by Olympus Corporation) at a magnification of 200× to observe whether the pattern remains neat to evaluate the resolution. When the outline of the pattern is more complete, the cured film has good resolution.

The evaluation criteria of resolution are as follows:
◯: the outline of the pattern is complete;
Δ: the outline of the pattern is slightly convex or missing, but it does not affect the actual application;
X: the outline of the pattern is not complete.

### c. Adhesion

The prepared cured film (thickness: 1.5 μm) was directly observed whether the cured film was peeled off from the substrate via the naked eye to evaluate the adhesion. When the pattern is less likely to be peeled off from the substrate, the cured film has good adhesion.

The evaluation criteria of adhesion are as follows:
◯: the pattern is not peeled off from the substrate;
Δ: the pattern is slightly peeled off from the substrate;
X: the pattern is severely peeled off from the substrate.

### d. Hardness

A cured film was prepared in the same manner as the above-mentioned preparation of the cured film for light-shielding property evaluation. The prepared cured film (thickness: 1.5 μm) was measured for a pencil hardness via a pencil hardness machine (Model: P247, manufactured by Prema Co., Ltd.) adopting the standard of ASTM D3363 to evaluate the hardness. When the pencil hardness is greater, the cured film has good hardness.

The evaluation criteria of hardness are as follows:
◯: 7H≤hardness;
Δ: 3H≤hardness<7H;
X: hardness<3H.

### e. Development Resistance

The prepared cured film (thickness: 1.5 μm) was directly observed whether the cured film had photosensitive resin composition remaining on the surface of the substrate in the non-exposed area via the naked eye to evaluate the development resistance. When the photosensitive resin composition remaining in the non-exposed area is less, the cured film has good development resistance.

The evaluation criteria of development resistance are as follows:
◯: there is no residual trace of development in the non-exposed area;
Δ: there are some residual traces of development in the non-exposed area;
X: there are obvious residual traces of development in the non-exposed area.

### Evaluation Results

It may be seen from Table 2 that when the photosensitive resin composition includes an alkali-soluble resin (A) including a resin including a specific structure having a fluorene ring and two or more ethylenically polymeric groups (A-1), an epoxy resin (A-2), or a combination thereof (Examples 1 to 3), the cured films formed by the photosensitive resin composition have good light-shielding property, resolution, adhesion, hardness and development resistance at the same time, and may be suitable for black matrixes.

In addition, compared to the cured film (Comparative example 1) formed by the photosensitive resin composition in which the alkali-soluble resin (A) does not include the resin including a specific structure having a fluorene ring and two or more ethylenically polymeric groups (A-1), the cured films (Examples 1 to 3) prepared by the photosensitive resin composition in which the alkali-soluble resin (A) includes the resin including a specific structure having a fluorene ring and two or more ethylenically polymeric groups (A-1) have better resolution and development resistance. Therefore, when the alkali-soluble resin (A) includes the resin including a specific structure having a fluorene ring and two or more ethylenically polymeric groups (A-1), the resin including a specific structure having a fluorene ring and two or more ethylenically polymeric groups (A-1) may improve the dispersibility in the photosensitive resin composition, so that the cured film formed by the photosensitive resin composition may have better resolution and development resistance, and have good light-shielding property, adhesion and hardness at the same time.

In addition, compared to the cured film (Comparative example 2) formed by the photosensitive resin composition in which the alkali-soluble resin (A) does not include the epoxy resin (A-2), the cured films (Examples 1 to 3) prepared by the photosensitive resin composition in which the alkali-soluble resin (A) includes the epoxy resin (A-2) have better resolution, adhesion and hardness. Therefore, when the alkali-soluble resin (A) includes the epoxy resin (A-2), the epoxy resin (A-2) may improve the crosslinking ability during curing, so that the cured film formed by the photosensitive resin composition may have better resolution, adhesion and hardness, and have good light-shielding property and development resistance at the same time.

In addition, compared to the cured film (Comparative example 3) formed by the photosensitive resin composition in which the ethylenically unsaturated monomer (B) does not include the bisphenol fluorene-based compound having an epoxy group (B-1), the cured films (Examples 1 to 3) prepared by the photosensitive resin composition in which the ethylenically unsaturated monomer (B) includes the bisphenol fluorene-based compound having an epoxy group (B-1) have better hardness. Therefore, when the ethylenically unsaturated monomer (B) includes the bisphenol fluorene-based compound having an epoxy group (B-1), the bisphenol fluorene-based compound having an epoxy group (B-1) may improve the crosslinking ability during curing, so that the cured film formed by the photosensitive resin composition may have better hardness, and have good light-shielding property, resolution, adhesion and development resistance at the same time.

In addition, compared to the cured film (Comparative example 4) formed by the photosensitive resin composition without the additive (G) including the silane compound having an epoxy group, the cured films (Examples 1 to 3) prepared by the photosensitive resin composition including the additive (G) including the silane compound having an epoxy group have better resolution and adhesion. Therefore, when the photosensitive resin composition includes the additive (G) and the additive (G) includes the silane compound having an epoxy group, the silane compound having an epoxy group may improve the adhesion between the photosensitive resin composition and the substrate, so that the cured film formed by the photosensitive resin composition may have better resolution and adhesion, and have good light-shielding property, hardness and development resistance at the same time.

Based on the above, when the photosensitive resin composition of the invention includes the alkali-soluble resin (A) and the alkali-soluble resin (A) includes a resin including a specific structure having a fluorene ring and two or more ethylenically polymeric groups (A-1), an epoxy resin (A-2), or a combination thereof, the cured film formed by the photosensitive resin composition has good light-shielding property, resolution, adhesion, hardness and development resistance at the same time, and may be suitable for black matrixes, thereby improving the performance of a device using the black matrix.

Although the invention has been disclosed in the embodiments above, they are not intended to limit the invention. Anyone with ordinary knowledge in the relevant technical field can make changes and modifications without departing from the spirit and scope of the invention. The scope of protection of the invention shall be subject to those defined by the claims attached.

What is claimed is:

1. A photosensitive resin composition, comprising:
an alkali-soluble resin (A) comprising a resin having a fluorene ring and two or more ethylenically polymeric groups (A-1), an epoxy resin (A-2), or a combination thereof, wherein the resin having a fluorene ring and two or more ethylenically polymeric groups (A-1) comprises a structural unit represented by Formula (A1) as follows;
an ethylenically unsaturated monomer (B);
a photoinitiator (C);
a thermal acid generator (D);
a black colorant (E); and
a solvent (F): 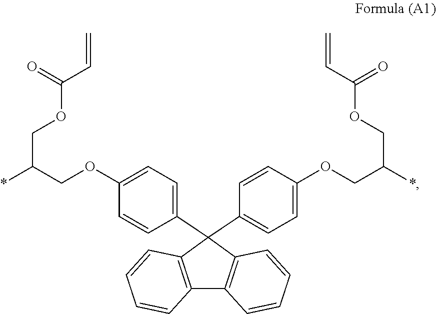
in Formula (A1), * represents a bonding position.

2. The photosensitive resin composition according to claim 1, wherein a weight average molecular weight of the resin having a fluorene ring and two or more ethylenically polymeric groups (A-1) is 2,000 to 20,000.

3. The photosensitive resin composition according to claim 1, wherein the epoxy resin (A-2) comprises at least one of a structural unit represented by Formula (A2) to Formula (A5) as follows: 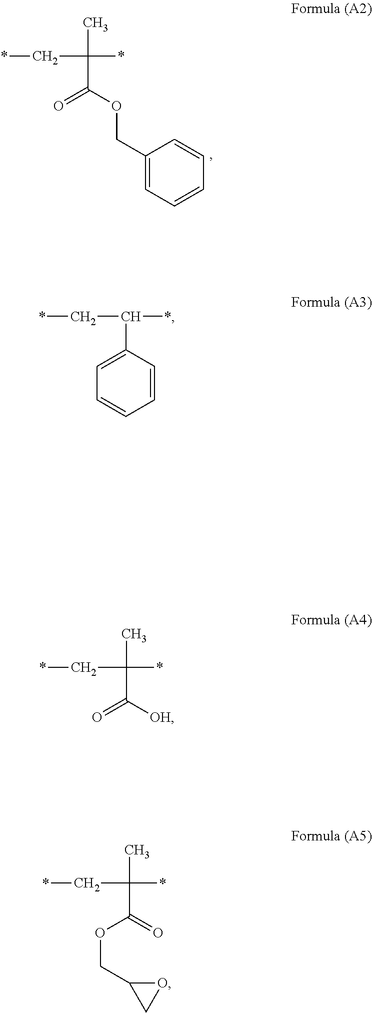
in Formula (A2) to Formula (A5), * represents a bonding position.

4. The photosensitive resin composition according to claim 3, wherein based on a total mole number of 100 mol % of the structural units in the epoxy resin (A-2), a mole number of the structural unit represented by Formula (A2) is 10 mol % to 40 mol %, a mole number of the structural unit represented by Formula (A3) is 5 mol % to 25 mol %, a mole number of the structural unit represented by Formula (A4) is 5 mol % to 25 mol %, a mole number of the structural unit represented by Formula (A5) is 20 mol % to 45 mol %.

5. The photosensitive resin composition according to claim 1, wherein a weight average molecular weight of the epoxy resin (A-2) is 11,000 to 18,000.

6. The photosensitive resin composition according to claim 1, wherein the ethylenically unsaturated monomer (B) comprises a bisphenol fluorene-based compound having an epoxy group (B-1), a compound having an ethylenically polymeric group (B-2), a multi-functional compound having an epoxy group (B-3), or a combination thereof.

7. The photosensitive resin composition according to claim 1, wherein the ethylenically unsaturated monomer (B) comprises a bisphenol fluorene-based compound having an epoxy group (B-1), the bisphenol fluorene-based compound having an epoxy group (B-1) comprises a compound represented by Formula (B1) as follows: 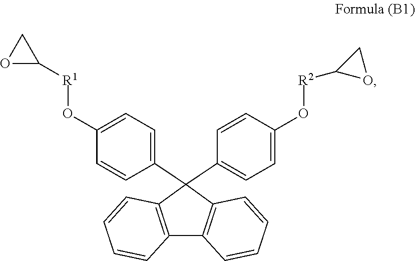
in Formula (B1), R¹ and R² each represent an alkyl group with 1 to 5 carbon atoms, an ether group, a phenyl group, an ester group, or a combination thereof.

8. The photosensitive resin composition according to claim 1, wherein the ethylenically unsaturated monomer (B) comprises a compound having an ethylenically polymeric group (B-2), the compound having an ethylenically polymeric group (B-2) comprises a compound represented by Formula (B2) as follows: 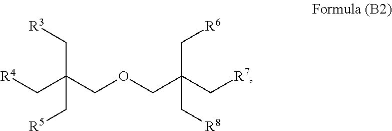
in Formula (B2), R³ to R⁸ each represent hydrogen, an alkyl group, an aryl group, an acrylate group, or a combination thereof.

9. The photosensitive resin composition according to claim 1, wherein the photoinitiator (C) comprises at least one selected from a group consisting of an oxime ester derivative, a halogenated hydrocarbon derivative and an alkyl acetophenone.

10. The photosensitive resin composition according to claim 1, wherein the thermal acid generator (D) comprises a hexafluoroonium salt.

11. The photosensitive resin composition according to claim 1, wherein based on a usage amount of 100 parts by weight of the alkali-soluble resin (A), a usage amount of the ethylenically unsaturated monomer (B) is 100 parts by weight to 190 parts by weight, a usage amount of the photoinitiator (C) is 10 parts by weight to 50 parts by weight, a usage amount of the thermal acid generator (D) is 60 parts by weight to 96 parts by weight, a usage amount of the black colorant (E) is 200 parts by weight to 250 parts by weight, a usage amount of the solvent (F) is 400 parts by weight to 480 parts by weight.

12. The photosensitive resin composition according to claim 1, further comprising an additive (G), wherein the additive (G) comprises a silane compound having an epoxy group.

13. The photosensitive resin composition according to claim 1, further comprising a surfactant (H), wherein the surfactant (H) comprises a polysiloxane-based surfactant, a cationic-based surfactant, an anionic-based surfactant, a fluorine-based surfactant, or a combination thereof.

14. A cured film formed by curing the photosensitive resin composition according to claim 1.

15. A black matrix being the cured film according to claim 14.
